(19) United States
(12) Patent Application Publication
(10) Pub. No.: US 2015/0187578 A1
(43) Pub. Date: Jul. 2, 2015

(54) METHOD OF FORMING SILICON LAYER, AND METHOD OF MANUFACTURING FLASH MEMORY

(71) Applicant: MACRONIX International Co., Ltd., Hsinchu (TW)

(72) Inventors: Pei-Ci Jhang, Hsinchu (TW); Jung-Yu Shieh, Hsinchu (TW)

(73) Assignee: MACRONIX International Co., Ltd., Hsinchu (TW)

(21) Appl. No.: 14/141,244

(22) Filed: Dec. 26, 2013

(51) Int. Cl. H01L 21/02; H01L 29/49; H01L 23/532; H01L 21/28

(52) U.S. Cl. CPC H01L 21/02694; H01L 21/28035; H01L 29/4933; H01L 23/53271

(57) ABSTRACT

A method of manufacturing a flash memory is provided. In the method, a hydrogen treatment is performed on a substrate, on which a polysilicon gate and a plurality of spacers on sidewalls of the polysilicon gate are formed. A silicon thin film is deposited on the polysilicon gate to extend a top area thereof. The hydrogen treatment and the deposition of the silicon thin film are accomplished repeatedly, and then a cobalt layer is deposited on the silicon thin film. A portion of the cobalt layer is converted to a CoSiₓ layer, and the unreacted cobalt layer is then removed.

### BACKGROUND OF THE INVENTION

1. Field of the Invention

The invention relates to a method of improving the formation of a silicon layer, and more particularly, to a method of forming silicon layer with high deposition selectivity on different materials.

2. Description of Related Art

As the integration density of a semiconductor device increases, the resistance of wire tends to be lower than previous semiconductor device. Currently, a metal silicide layer stacked on a polysilicon layer has been widely used as a low-resistance wire structure for a bit line, a gate electrode, and so on.

In light of process integration, a CoSiₓ layer is widely used as gate in current process. However, due to shrinkage of the CoSiₓ gate, it may cause the sheet resistance degradation.

### SUMMARY OF THE INVENTION

The invention provides a method of manufacturing a flash memory to reduce the resistance of the CoSiₓ layer.

The invention further provides a method of depositing a silicon layer selectively.

The invention further provides a method of forming a silicon layer on a silicon oxide layer quickly.

The invention further provides a conductive structure.

An exemplary embodiment of the present invention includes a method of manufacturing a flash memory. In the method, a hydrogen treatment is performed on a substrate, on which a polysilicon gate and a plurality of spacers on sidewalls of the polysilicon gate are formed. A silicon thin film is then deposited on the polysilicon gate to extend a top area thereof. The steps of performing the hydrogen treatment and depositing the silicon thin film are repeated at least one time, and then a cobalt layer is deposited on the silicon thin film. A portion of the cobalt layer is converted to a CoSi, layer, and the unreacted cobalt layer is then removed.

In one embodiment of the invention, a material of the spacers comprises silicon oxide.

In one embodiment of the invention, the polysilicon gate is pre-cleaned before the step of performing the hydrogen treatment.

In one embodiment of the invention, a time of the hydrogen treatment is 30-60 seconds.

In one embodiment of the invention, a temperature range of the hydrogen treatment is 300-500° C.

In one embodiment of the invention, a power of the hydrogen treatment is higher than 100 W.

In one embodiment of the invention, a deposition time of depositing the silicon thin film is 90-150 seconds.

In one embodiment of the invention, a deposition temperature of depositing the silicon thin film is 400-500° C.

Another exemplary embodiment of the present invention includes a method of selectively depositing a silicon layer. In the method, a substrate is provided on which a polysilicon portion and a silicon oxide portion are disposed, and a hydrogen treatment is performed on the substrate. Thereafter, a silicon thin film is deposited on the substrate to cover the polysilicon portion and the silicon oxide layer. The steps of performing the hydrogen treatment and depositing the silicon thin film are repeated at least one time, such that a deposition selectivity of the silicon thin film on the polysilicon portion is higher than that on the silicon oxide portion.

In another embodiment of the invention, the polysilicon portion is pre-cleaned before the step of performing the hydrogen treatment.

In another embodiment of the invention, a time of the hydrogen treatment is 30-60 seconds

In another embodiment of the invention, a temperature range of the hydrogen treatment is 300-500° C.

In another embodiment of the invention, a power of the hydrogen treatment is higher than 100 W.

Yet another exemplary embodiment of the present invention includes a method of forming a silicon layer. In the method, a hydrogen treatment is performed on a silicon oxide layer, and then a silicon layer is deposited on the treated silicon oxide layer, wherein a deposition selectivity of the silicon layer on the treated silicon oxide layer is higher than that on the untreated silicon oxide layer.

Another exemplary embodiment of the present invention includes a conductive structure. The conductive structure includes a conductive layer with a lateral protrusion structure and a metal silicide. The lateral protrusion structure is on a top surface of the conductive layer, and the metal silicide on a top surface of the lateral protrusion structure.

In another embodiment of the invention, a thickness of the lateral protrusion structure is 10-20 Å.

In another embodiment of the invention, a material of the lateral protrusion structure comprises silicon.

In another embodiment of the invention, a material of the conductive layer comprises polysilicon.

In another embodiment of the invention, a material of the metal silicide comprises CoSiₓ.

Based on the above, according to the embodiment of the present invention, the deposition selectivity of the silicon layer may be improved by the hydrogen treatment. Moreover, if the CoSiₓ layer on the polysilicon gate is formed according to the embodiment of the present invention, it could restrain CoSiₓ layer shrinkage in contrast to the CoSiₓ layer formed on a polysilicon gate without hydrogen treatment. In addition, a silicon layer may have high deposition selectivity on a silicon oxide layer through the hydrogen treatment.

It is to be understood that both the foregoing general description and the following detailed description are exemplary, and are not intended to limit the scope of the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1E, are schematic cross-sectional views illustrating a process flow of manufacturing a flash memory according to an exemplary embodiment of the invention.

FIGS. 2A to 2D are schematic cross-sectional views illustrating an example of the invention.

### DESCRIPTION OF THE EMBODIMENTS

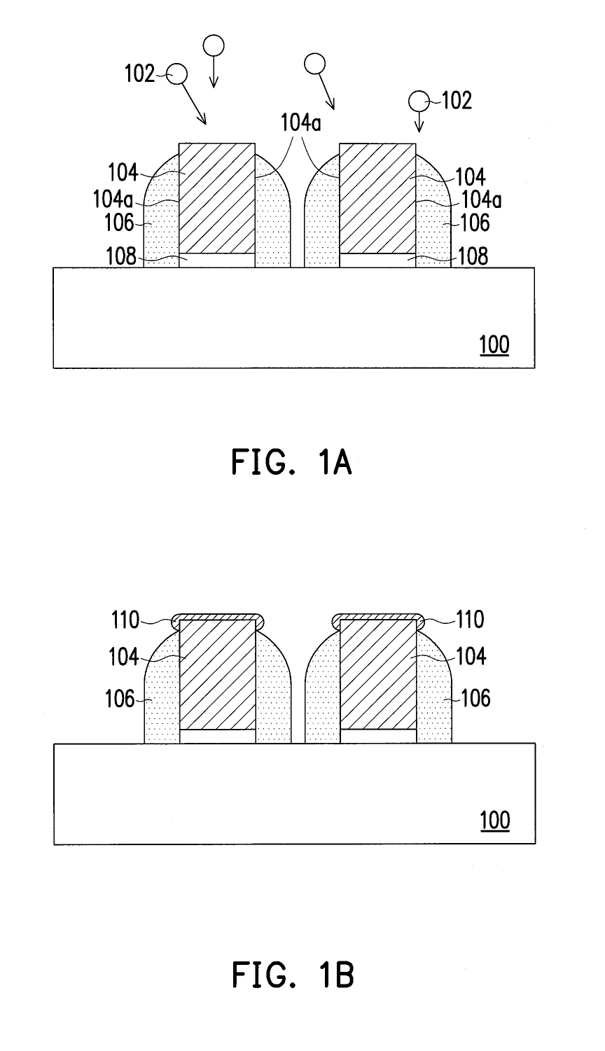

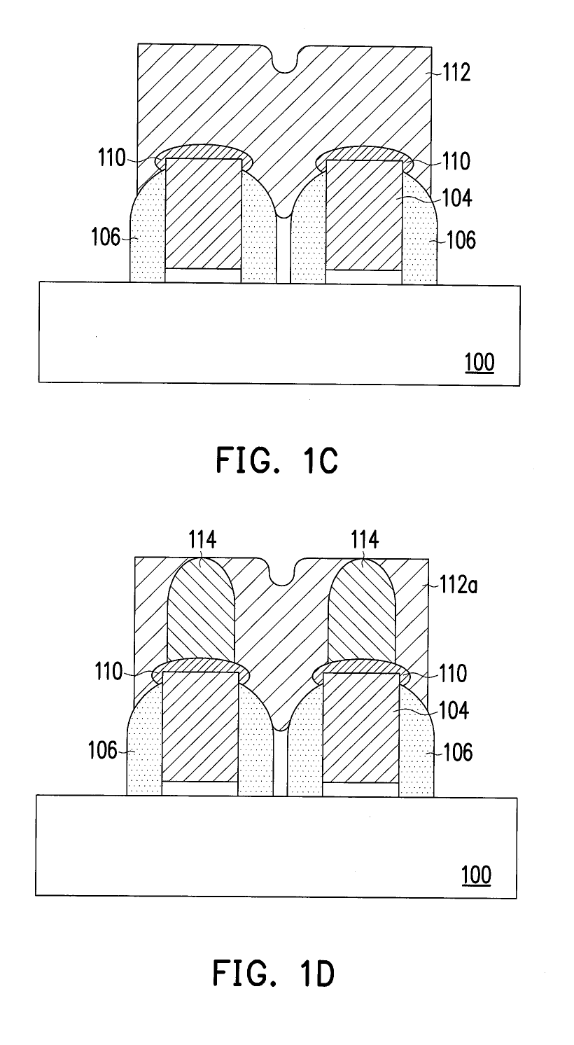

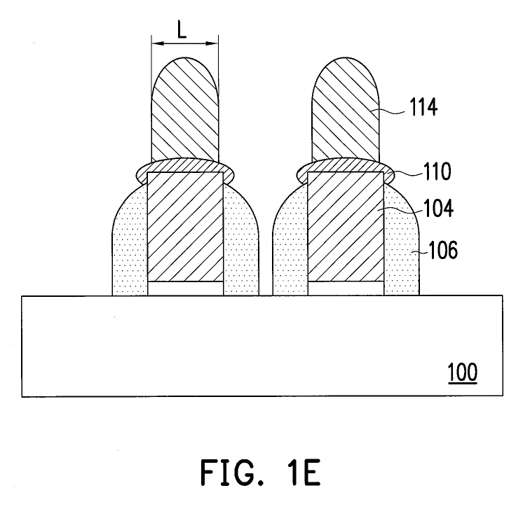

FIGS. 1A to 1E are schematic cross-sectional views illustrating a process flow of manufacturing a flash memory according to an exemplary embodiment of the invention.

Referring to FIG. 1A, a hydrogen (H₂) treatment 102 is performed on a substrate 100. In the hydrogen treatment 102, the time may be 30-60 seconds, a range of temperature may be 300-500° C., and a power may be higher than 100 W, for example. There is a polysilicon gate 104 and a plurality of spacers 106 on sidewalls 104a of the polysilicon gate 104 on the substrate 100. For example, a material of the spacers 106 is silicon oxide. An oxide-nitride-oxide (ONO) layer 108 is formed between the substrate 100 and the polysilicon gate 104, for example. Moreover, before the step of performing the hydrogen treatment 102, the polysilicon gate 104 may be pre-cleaned to remove native oxide thereon.

Referring to FIG. 1B, a silicon thin film 110 is deposited on the polysilicon gate 104 to extend a top area of the polysilicon gate 104, wherein a thickness of the silicon thin film 110 may be 10-20 Å, for instance. For example, a method of depositing the silicon thin film 110 includes LPCVD and so on. Moreover, a deposition time may be 90-150 seconds, and a deposition temperature may be 400-500° C.

After that, the steps shown in FIGS. 1A and 1B are repeated at least one time, whereby thickening the silicon thin film 110, and meantime the increase in thickness of the silicon thin film 110 on the polysilicon gate 104 is widely larger than that on the spacers 106 due to deposition selectivity. The so-called deposition selectivity means to a ratio of different deposition rates of the silicon thin film 110 on various materials (i.e. the polysilicon gate 104 and the spacer 106). In other words, the deposition selectivity of the silicon thin film 110 on the polysilicon gate 104 is higher than that on the spacer 106.

Referring to FIG. 1C, a cobalt layer 112 is deposited on the silicon thin film 110 after repeating the hydrogen treatment 102 and the deposition of the silicon thin film 110. In addition, the cobalt layer 112 may cover a portion of spacers 106.

Referring to FIG. 1D, a portion of the cobalt layer is converted to a CoSi layer 114, and the CoSi, layer 114 is on the silicon thin film 110. The unreacted cobalt layers 112a are around the CoSiₓ layers 114.

Referring to FIG. 1E, the unreacted cobalt layer 112a is removed. Since the top area of the polysilicon gate 104 is extended by using sequence hydrogen treatment (102 in FIG. 1A) and silicon deposition (110 in FIG. 1B) before the formation of the CoSiₓ layer 114, a width L of the CoSiₓ layer 114 is sufficient for electrical conductance, and thus it is possible to reduce the sheet resistance of the gate structure consisting of the polysilicon gate 104, the silicon thin film 110 and the CoSiₓ layer 114.

Even through FIGS. 1A to 1E show the exemplary embodiment of the invention, the invention can still be implemented in many other different forms and should not be construed as limited to the embodiment described above. For example, the structure consisting of the polysilicon gate 104, the silicon thin film 110 and the CoSiₓ layer 114 may function as a conductive structure. In particular, the reference numeral 104 represents a conductive layer, and the reference numeral 110 represents a lateral protrusion structure on a top surface of the conductive layer 104. A material of the conductive layer 104 may be polysilicon or suitable conductive material. A material of the lateral protrusion structure 110 may be silicon or suitable conductive material, and a thickness of the lateral protrusion structure 110 may be 10-20 Å, for instance. Moreover, the reference numeral 114 represents a metal silicide such as CoSiₓ or the like. The metal silicide 114 is on a top surface of the lateral protrusion structure 110.

The following example is described for illustration.

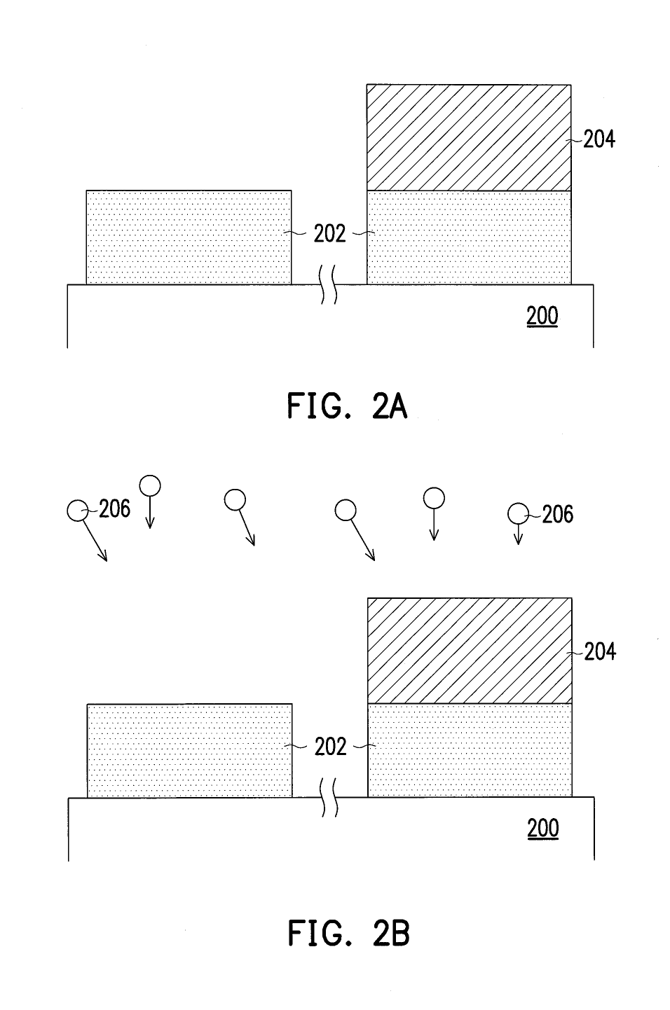

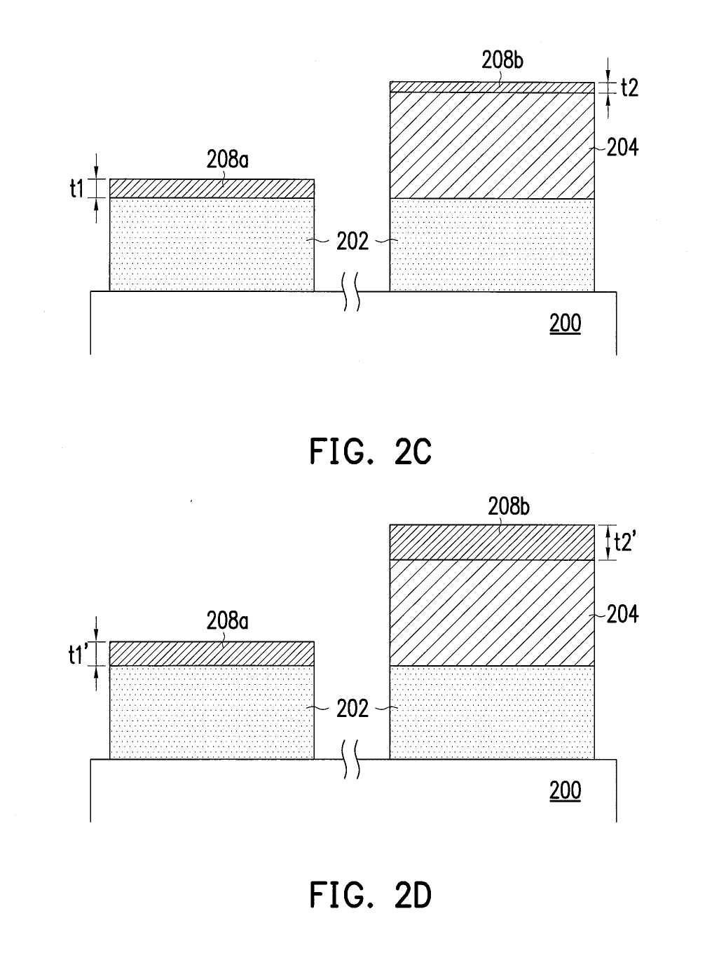

FIGS. 2A to 2D are schematic cross-sectional views illustrating the example of the invention.

In FIG. 2A, a substrate 200 is provided, and a silicon oxide portion 202 and a polysilicon portion 204 are disposed on the substrate 200. Afterwards, the polysilicon portion 204 may be pre-cleaned to remove native oxide. In FIG. 2B, a hydrogen treatment 206 is performed on the substrate 200. In the hydrogen treatment 206, the time may be 30-60 seconds, a range of temperature may be 300-500° C., and a power may be higher than 100 W, for example. Thereafter, in FIG. 2C, the silicon thin film 208a and 208b are simultaneously deposited on the silicon oxide layer 202 and the polysilicon portion 204. The silicon thin film 208b on the polysilicon portion 204 has a thickness t2 less than a thickness t1 of the silicon thin film 208a on the silicon oxide layer 202. Hence, the deposition selectivity of the silicon layer (i.e. the silicon thin film 208a) on the treated silicon oxide portion 202 is higher than of the silicon layer (i.e. the silicon thin film 208b) on the treated polysilicon portion 204.

After that, the steps of performing the hydrogen treatment and depositing the silicon thin film are repeated once. Accordingly, the silicon thin film 208b on the polysilicon portion 204 has a thickness t2′ larger than a thickness t1′ of the silicon thin film 208a on the silicon oxide layer 202 in FIG. 2D. Therefore, it is proved that the deposition selectivity of the silicon thin film 208b on the polysilicon portion 204 is higher than that on the silicon oxide portion 202.

In other words, according to the foregoing example, a silicon layer may be selectively deposited on different materials in sequence H₂ treatment and silicon deposition.

Furthermore, as above reason, if a silicon oxide layer is treated by the hydrogen treatment, its surface would be transferred to Si—H surface, and thus the growth rate of silicon on the Si—H surface should be faster than on the Si—O surface. Therefore, a deposition selectivity of a silicon layer on the treated silicon oxide layer may be higher than that on the untreated silicon oxide layer. In another embodiment of the invention, a silicon layer can be selectively formed on a portion of the silicon oxide layer undergone the hydrogen treatment.

Based on the above, since the embodiments of the invention provide sequence H₂ treatment and silicon deposition before Co deposition, and thus the Si area can be to extended for solving the issue of CoSix gate shrinkage. Moreover, in comparison with raw silicon oxide layer, a silicon layer may have high deposition selectivity on the silicon oxide layer through the hydrogen treatment.

Although the present invention has been described with reference to the above embodiments, it will be apparent to one of the ordinary skill in the art that modifications to the described embodiments may be made without departing from the spirit of the invention. Accordingly, the scope of the invention is defined by the attached claims not by the above detailed descriptions.

1. A method of manufacturing a flash memory, comprising:
performing a hydrogen treatment on a substrate, on which a polysilicon gate and a plurality of spacers on sidewalls of the polysilicon gate are formed;
performing LPCVD to deposit a silicon thin film on the polysilicon gate to extend a top area of the polysilicon gate, wherein a deposition selectivity of the silicon thin film on the polysilicon gate is higher than that on the plurality of spacers;
repeating the steps of performing the hydrogen treatment and depositing the silicon thin film at least one time;
depositing a cobalt layer on the silicon thin film;
converting a portion of the cobalt layer to a CoSiₓ layer; and
removing the unreacted cobalt layer.

2. The method of claim 1, wherein a material of the spacers comprises silicon oxide.

3. The method of claim 1, further comprising pre-cleaning the polysilicon gate before the step of performing the hydrogen treatment.

4. The method of claim 1, wherein a time of the hydrogen treatment is 30-60 seconds.

5. The method of claim 1, wherein a temperature range of the hydrogen treatment is 300-500° C.

6. The method of claim 1, wherein a power of the hydrogen treatment is higher than 100 W.

7. The method of claim 1, wherein a deposition time of depositing the silicon thin film is 90-150 seconds.

8. The method of claim 1, wherein a deposition temperature of depositing the silicon thin film is 400-500° C.

9. A method of selectively depositing a silicon layer, comprising:
providing a substrate, on which a polysilicon portion and a silicon oxide portion are disposed;
performing a hydrogen treatment on the substrate;
performing LPCVD to deposit a silicon thin film on the substrate to cover the polysilicon portion and the silicon oxide layer;
repeating the steps of performing the hydrogen treatment and depositing the silicon thin film at least one time, such that a deposition selectivity of the silicon thin film on the polysilicon portion is higher than that on the silicon oxide portion.

10. The method of claim 9, further comprising pre-cleaning the polysilicon portion before the step of performing the hydrogen treatment.

11. The method of claim 9, wherein a time of the hydrogen treatment is 30-60 seconds.

12. The method of claim 9, wherein a temperature range of the hydrogen treatment is 300-500° C.

13. The method of claim 9, wherein a power of the hydrogen treatment is higher than 100 W.

14. A method of forming a silicon layer, comprising:
performing a hydrogen treatment on a silicon oxide layer; and
performing LPCVD to deposit a silicon layer on the treated silicon oxide layer, wherein a deposition selectivity of the silicon layer on the treated silicon oxide layer is higher than that on the silicon oxide layer without performing the hydrogen treatment.

15. A conductive structure, comprising:
a conductive layer with a lateral protrusion structure on a top surface of the conductive layer; and
a metal silicide on a top surface of the lateral protrusion structure, wherein a width of the metal silicide is less than that of the conductive layer, and a portion of the lateral protrusion structure is exposed from the metal silicide.

16. The conductive structure of claim 15, wherein a thickness of the lateral protrusion structure is 10-20 Å.

17. The conductive structure of claim 15, wherein a material of the lateral protrusion structure comprises silicon.

18. The conductive structure of claim 15, wherein a material of the conductive layer comprises polysilicon.

19. The conductive structure of claim 15, wherein a material of the metal silicide comprises CoSiₓ.
